(19) United States
(12) Patent Application Publication
(10) Pub. No.: US 2011/0189508 A1
(43) Pub. Date: Aug. 4, 2011

(54) PRINTED CIRCUIT BOARD AND FUEL CELL INCLUDING THE SAME

(75) Inventors: Shinichi INOUE, Osaka (JP); Hiroyuki HANAZONO, Osaka (JP)

(73) Assignee: NITTO DENKO CORPORATION, Osaka (JP)

(21) Appl. No.: 13/019,460

(22) Filed: Feb. 2, 2011

(30) Foreign Application Priority Data
Feb. 4, 2010 (JP) 2010-023353
Jan. 19, 2011 (JP) 2011-008659

(51) Int. Cl. H01M 14/00; H01M 8/00; H05K 1/00; H05K 1/09

(52) U.S. Cl. 429/7; 174/258; 174/257

(57) ABSTRACT

Collector portions, connection conductor portions and drawn-out conductor portions are formed on one surface of a base insulting layer of an FPC board. The collector portions, the connection conductor portions and the drawn-out conductor portions are covered with cover layers. The cover layers contain a resin composition. The resin composition has moisture permeability of not more than 150 g/(m²·24 h) in an environment at a temperature of 40° C. and with a relative humidity of 90%. The resin composition has a glass transition temperature of not less than 80° C.

### BACKGROUND OF THE INVENTION

1. Field of the Invention

The present invention relates to a printed circuit board and a fuel cell including the same.

2. Description of the Background Art

Batteries that are small in size and have high capacity are desired for mobile equipment such as cellular telephones. Therefore, fuel cells capable of providing higher energy density than conventional batteries including lithium secondary batteries have been developed. Examples of the fuel cells include a direct methanol fuel cell.

In the direct methanol fuel cell, methanol is decomposed by a catalyst, forming hydrogen ions. The hydrogen ions are reacted with oxygen in the air to generate electrical power. In this case, chemical energy can be converted into electrical energy with extremely high efficiency, so that significantly high energy density can be obtained.

In the inside of such a direct methanol fuel cell, a flexible printed circuit board (hereinafter abbreviated as an FPC board) is bent, and an electrode film composed of a fuel electrode, an air electrode and an electrolyte film is arranged between portions of the bent FPC board (see JP 2008-300238 A, for example).

A conductor layer is formed in a given pattern on a base insulating layer in the FPC board described in JP 2008-300238 A. The conductor layer is covered with an electrically conductive cover layer containing carbon black or graphite. This prevents the conductor layer from corroding because of adhesion of methanol or the like, and ensures electrical conductivity between the electrode film and the conductor layer.

It is desirable that the conductor layer has improved corrosion resistance in order to allow such an FPC board to be used over a longer period of time.

### BRIEF SUMMARY OF THE INVENTION

An object of the present invention is to provide a printed circuit board in which a conductor layer can be sufficiently prevented from corroding and electrical conductivity between an electrode film and the conductor layer can be ensured, and a fuel cell including the same.

(1) According to one aspect of the present invention, a printed circuit board to be used in a fuel cell includes an insulating layer, a conductor layer that is provided in a given pattern on the insulating layer, and a cover layer that covers a surface of the conductor layer, wherein the cover layer contains an electrically conductive material and a resin composition, and the resin composition has moisture permeability of not more than 150 g/(m²·24 h) in an environment at a temperature of 40° C. and with a relative humidity of 90%.

In the printed circuit board, the surface of the conductor layer that is provided in the given pattern on the insulating layer is covered with the cover layer. The resin composition of the cover layer has the moisture permeability of not more than 150 g/(m²·24 h) in the environment at a temperature of 40° C. and with a relative humidity of 90%. In this case, a fuel of the fuel cell or products derived from the fuel are prevented from permeating through the cover layer and adhering to the conductor layer. This sufficiently prevents the conductor layer of the printed circuit board from corroding.

(2) The cover layer may contain not less than 5 parts by weight and not more than 70 parts by weight of the electrically conductive material relative to 100 parts by weight of the resin composition. In this case, the conductor layer of the printed circuit board is sufficiently prevented from corroding while electrical conductivity of the cover layer is sufficiently ensured.

(3) The resin composition may include at least one of phenol resin, epoxy resin, acrylic resin, polyurethane resin, polyimide resin, polyamide imide resin and polyester resin. In this case, better flexibility of the printed circuit board is obtained. Particularly, when the resin composition includes phenol resin or epoxy resin, better flexibility and better chemical resistance of the printed circuit board are obtained.

(4) The electrically conductive material may include at least one of a metal material, a carbon material and an electrically conductive polymeric material. In this case, the electrical conductivity of the cover layer can be more sufficiently ensured.

(5) The metal material may include silver. In this case, the electrical conductivity of the cover layer can be further sufficiently ensured.

(6) The carbon material may include at least one of carbon black and graphite. In this case, the electrical conductivity of the cover layer can be further sufficiently ensured.

(7) According to another aspect of the present invention, a fuel cell includes the printed circuit board according to the one aspect of the present invention, a cell element, and a housing that accommodates the printed circuit board and the cell element.

In the fuel cell, the above-described printed circuit board and the cell element are accommodated in the housing. Electric power generated by the cell element is supplied to the outside of the housing through the printed circuit board.

In the printed circuit board, a fuel of the fuel cell or products derived from the fuel are prevented from permeating through the cover layer and adhering to the conductor layer. This sufficiently prevents the conductor layer of the printed circuit board from corroding. As a result, reliability of the fuel cell can be improved, and the fuel cell can be used over a longer period of time.

(8) According to still another aspect of the present invention, a printed circuit board to be used in a fuel cell includes an insulating layer, a conductor layer that is provided in a given pattern on the insulating layer, and a cover layer that covers a surface of the conductor layer, wherein the cover layer contains an electrically conductive material and a resin composition, and the resin composition has a glass transition temperature of not less than 80° C.

In the printed circuit board, the surface of the conductor layer that is provided in the given pattern on the insulating layer is covered with the cover layer. The resin composition of the cover layer has the glass transition temperature of not less than 80° C. In this case, a fuel of the fuel cell or products derived from the fuel are prevented from permeating through the cover layer and adhering to the conductor layer even though the thickness of the cover layer is small. This sufficiently prevents the conductor layer of the printed circuit board from corroding.

(9) The cover layer may contain not less than 5 parts by weight and not more than 70 parts by weight of the electrically conductive material relative to 100 parts by weight of the resin composition. In this case, the conductor layer of the printed circuit board is sufficiently prevented from corroding while electrical conductivity of the cover layer is sufficiently ensured.

(10) The resin composition may include at least one of phenol resin, epoxy resin, acrylic resin, polyurethane resin, polyimide resin, polyamide imide resin and polyester resin. In this case, better flexibility of the printed circuit board is obtained. Particularly, when the resin composition includes phenol resin or epoxy resin, better flexibility and better chemical resistance of the printed circuit board are obtained.

(11) The electrically conductive material may include at least one of a metal material, a carbon material and an electrically conductive polymeric material. In this case, the electrical conductivity of the cover layer can be more sufficiently ensured.

(12) The metal material may include silver. In this case, the electrical conductivity of the cover layer can be further sufficiently ensured.

(13) The carbon material may include at least one of carbon black and graphite. In this case, the electrical conductivity of the cover layer can be further sufficiently ensured.

(14) According to yet another aspect of the present invention, a fuel cell includes the printed circuit board according to the still another aspect of the present invention, a cell element, and a housing that accommodates the printed circuit board and the cell element.

In the fuel cell, the above-described printed circuit board and the cell element are accommodated in the housing. Electric power generated by the cell element is supplied to the outside of the housing through the printed circuit board.

In the printed circuit board, a fuel of the fuel cell or products derived from the fuel are prevented from permeating through the cover layer and adhering to the conductor layer. This sufficiently prevents the conductor layer of the printed circuit board from corroding. As a result, reliability of the fuel cell can be improved, and the fuel cell can be used over a longer period of time.

Other features, elements, characteristics, and advantages of the present invention will become more apparent from the following description of preferred embodiments of the present invention with reference to the attached drawings.

### BRIEF DESCRIPTION OF THE SEVERAL VIEWS OF THE DRAWINGS

FIG. 1 (a) is a plan view of a flexible printed circuit board according to a first embodiment;

FIG. 1 (b) is a sectional view of the flexible printed circuit board taken along the line A-A of FIG. 1 (a);

FIGS. 2 (a) to (d) are sectional views for use in illustrating steps in a method of manufacturing the FPC board;

FIGS. 3 (a) to (c) are sectional views for use in illustrating steps in the method of manufacturing the FPC board;

FIG. 4 (a) is an external perspective view of a fuel cell using the FPC board;

FIG. 4 (b) is a diagram for illustrating a function in the fuel cell of FIG. 4 (a); and

FIG. 5 is a schematic sectional view of the FPC board used in each of inventive examples 1 to 8 and comparative examples 1 to 5.

### DETAILED DESCRIPTION OF THE INVENTION

### [1] First Embodiment

A printed circuit board according to a first embodiment of the present invention will be described while referring to the drawings. A flexible printed circuit board having a flexuous property is described as an example of the printed circuit board in the present embodiment.

(1) Configuration of the Flexible Printed Circuit Board

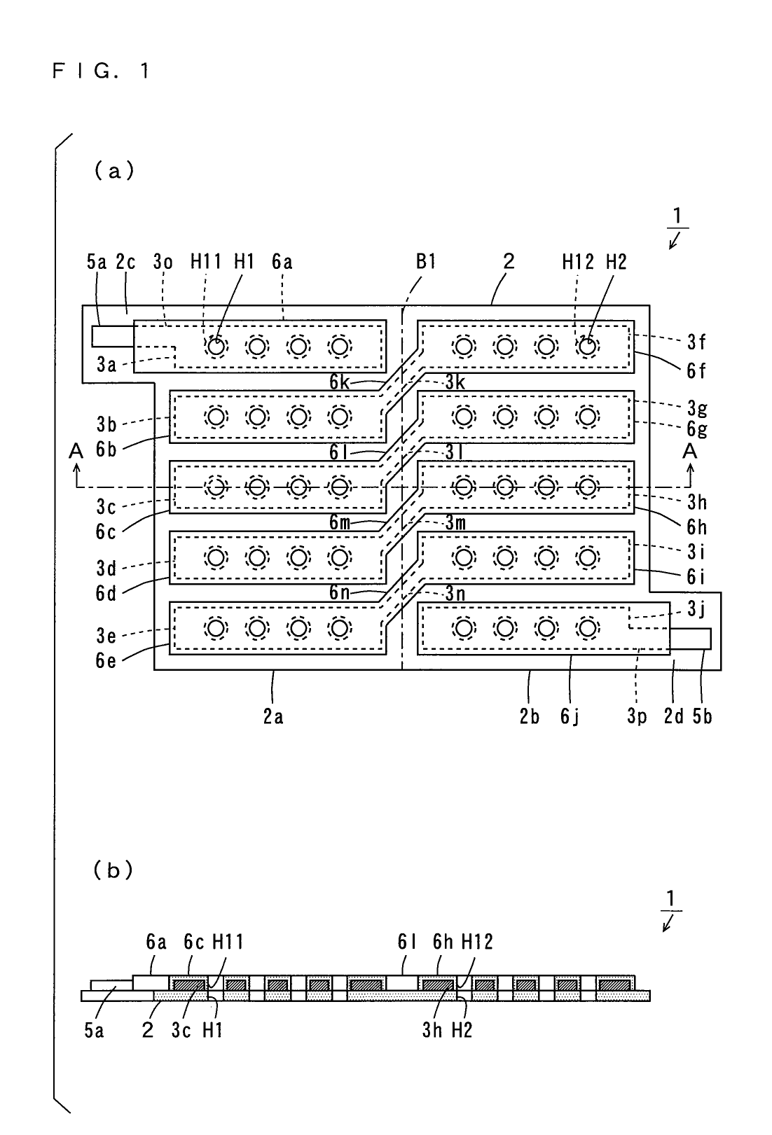

FIG. 1 (a) is a plan view of the flexible printed circuit board according to the first embodiment, and FIG. 1 (b) is a sectional view of the flexible printed circuit board taken along the line A-A of FIG. 1 (a). In the following description, the flexible printed circuit board is abbreviated as the FPC board.

As shown in FIGS. 1 (a) and (b), the FPC board 1 includes a base insulating layer 2 made of polyimide, for example. The base insulating layer 2 is composed of a first insulating portion 2a, a second insulating portion 2b, a third insulating portion 2c and a fourth insulating portion 2d. The first insulating portion 2a and the second insulating portion 2b each have a rectangular shape, and integrally formed while being adjacent to each other. Hereinafter, sides that are parallel to a border line between the first insulating portion 2a and the second insulating portion 2b are referred to as lateral sides, and a pair of sides that are perpendicular to the lateral sides of the first insulating portion 2a and the second insulating portion 2b are referred to as end sides.

The third insulating portion 2c extends outward from part of the lateral side at a corner of the first insulating portion 2a. The fourth insulating portion 2d extends outward from part of the lateral side at a corner of the second insulating portion 2b on the diagonal position of the foregoing corner of the first insulating portion 2a.

A bend portion B1 is provided on the border line between the first insulating portion 2a and the second insulating portion 2b so as to divide the base insulating layer 2 into two substantially equal parts. As will be described below, the base insulating layer 2 can be bent along the bend portion B1. The bend portion B1 may be a shallow groove with a line shape, a mark with a line shape or the like, for example. Alternatively, there may be nothing at the bend portion B1 if the base insulating layer 2 can be bent at the bend portion B1. When the base insulating layer 2 is bent along the bend portion B1, the first insulating portion 2a and the second insulating portion 2b are opposite to each other. In this case, the third insulating portion 2c and the fourth insulating portion 2d are not opposite to each other.

A plurality of (twenty in total in this example: four along an end side direction and five along a lateral side direction) openings H1 are formed in the first insulating portion 2a. A plurality of (twenty in total in this example: four along the end side direction and five along the lateral side direction) openings H2 are formed in the second insulating portion 2b.

Rectangular collector portions 3a, 3b, 3c, 3d, 3e, 3f, 3g, 3h, 3i, 3j, connection conductor portions 3k, 3l, 3m, 3n and drawn-out conductor portions 3o, 3p are formed on one surface of the base insulating layer 2. The collector portions 3a to 3j, the connection conductor portions 3k to 3n and the drawn-out conductor portions 3o, 3p are made of copper, for example.

Each of the collector portions 3a to 3j has a rectangular shape. The collector portions 3a to 3e extend parallel to the end sides of the first insulating portion 2a, and provided along the lateral side direction of the first insulating portion 2a. Here, each of the collector portions 3a to 3e is formed on a region of the first insulating portion 2a including four openings H1 that are arranged parallel to the end sides of the first insulating portion 2a.

Similarly, the collector portions 3f to 3j extend parallel to the end sides of the second insulating portion 2b, and provided along the lateral side direction of the second insulating portion 2b. Here, each of the collector portions 3f to 3j is formed in a region of the second insulating portion 2b including four openings H2 that are arranged parallel to the end sides of the second insulating portion 2b.

In this case, the collector portions 3a to 3e and the collector portions 3f to 3j are symmetrically arranged with respect to the bend portion B1.

Each of the connection conductor portions 3k to 3n is formed on the first insulating portion 2a and the second insulating portion 2b so as to cross the bend portion B1. The connection conductor portion 3k electrically connects the collector portion 3b and the collector portion 3f, the connection conductor portion 3I electrically connects the collector portion 3c and the collector portion 3g, the connection conductor portion 3m electrically connects the collector portion 3d and the collector portion 3h, and the connection conductor portion 3n electrically connects the collector portion 3e and the collector portion 3i.

Openings H11 each having a larger diameter than the opening H1 are formed in respective portions of the collector portions 3a to 3e above the openings H1 of the first insulating portion 2a. Openings H12 each having a larger diameter than the opening H2 are formed in respective portions of the collector portions 3f to 3j above the openings H2 of the second insulating portion 2b.

The drawn-out conductor portion 3o is formed to linearly extend from the outer short side of the collector portion 3a to the third insulating portion 2c. The drawn-out conductor portion 3p is formed to linearly extend from the outer short side of the collector portion 3j to the fourth insulating portion 2d.

A cover layer 6a is formed on the first insulating portion 2a to cover the collector portion 3a and part of the drawn-out conductor potion 3o. Thus, the tip of the drawn-out conductor portion is not covered with the cover layer 6a to be exposed. The exposed portion of the drawn-out conductor portion 3o is referred to as a drawn-out electrode 5a. Cover layers 6b, 6c, 6d, 6e are formed on the first insulating portion 2a to cover the collector portions 3b to 3e, respectively. The cover layers 6a to 6e come in contact with an upper surface of the first insulating portion 2a inside the openings H11 of the collector portions 3a to 3e, respectively.

A cover layer 6j is formed on the second insulating portion 2b to cover the collector portion 3j and part of the drawn-out conductor potion 3p. Thus, the tip of the drawn-out conductor portion 3p is not covered with the cover layer 6j to be exposed. The exposed portion of the drawn-out conductor portion 3p is referred to as a drawn-out electrode 5b. Cover layers 6f, 6g, 6h, 6i are formed on the second insulating portion 2b to cover the collector portions 3f to 3i, respectively. The cover layers 6f to 6j come in contact with an upper surface of the second insulating portion 2b inside the openings H12 of the collector portions 3f to 3j, respectively.

Cover layers 6k, 6l, 6m, 6n are formed on the first insulating portion 2a and the second insulating portion 2b to cover the connection conductor portions 3k to 3n, respectively.

Each of the cover layers 6a to 6n is made of a resin composition containing an electrically conductive material. For example, phenol resin, epoxy resin, acrylic resin, polyurethane resin, polyimide resin, polyamide imide resin, polyester resin or resin obtained by mixing at least two kinds of the foregoing resin can be used as the resin composition. In this case, better flexibility of the FPC board 1 is obtained. Particularly, when the resin composition includes phenol resin or epoxy resin, better flexibility and better chemical resistance of the FPC board 1 are obtained.

The resin composition has moisture permeability of not more than 150 g/(m²·24 h) in an environment at a temperature of 40° C. and with a relative humidity of 90%. The resin composition has a glass transition temperature Tg of not less than 80° C.

Meanwhile, a metal material such as gold (Au), silver or silver nanoparticles, a carbon material such as carbon black, graphite or carbon nanotube, an electrically conductive polymeric material such as polythiophene or polyaniline, or a material obtained by mixing at least two kinds of the foregoing materials can be used as the electrically conductive material, for example.

The cover layers 6a to 6n preferably contain not less than 5 parts by weight and not more than 70 parts by weight of the electrically conductive material relative to 100 parts by weight of the resin composition. In this case, sufficient electrical conductivity can be given to the cover layers 6a to 6n, and increase in moisture permeability and decrease in the glass transition temperature Tg of the resin composition can be prevented.

(2) Method of Manufacturing the FPC Board

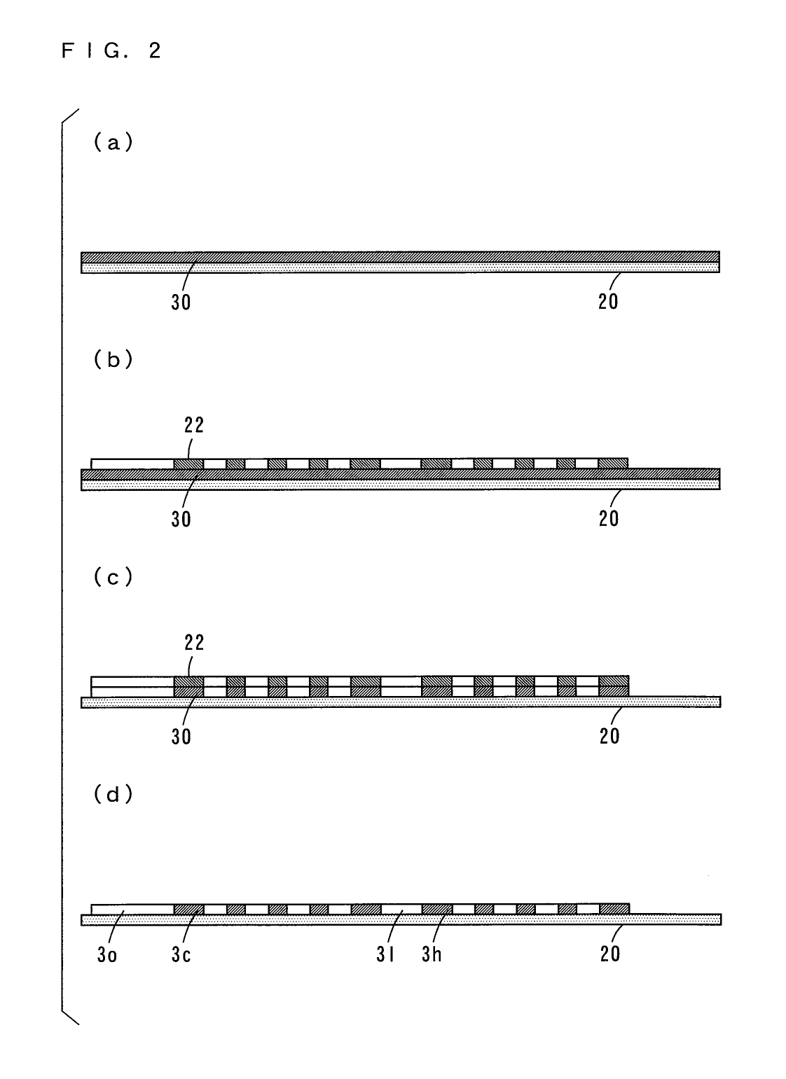

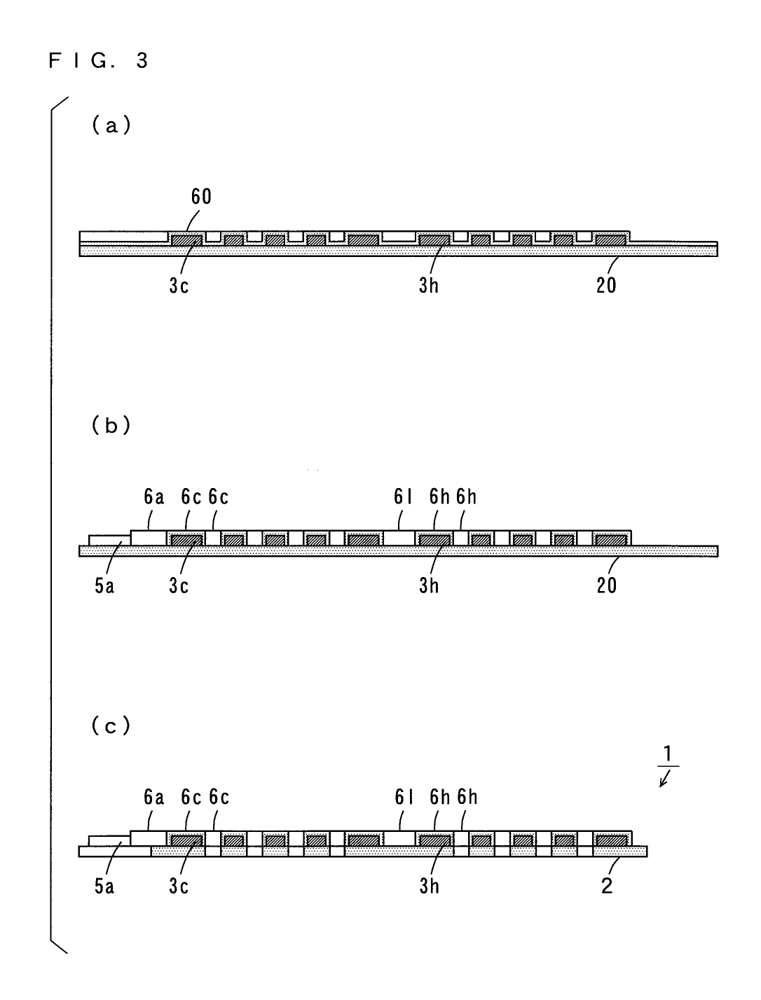

Next, description is made of a method of manufacturing the FPC board 1 shown in FIG. 1. FIGS. 2 and 3 are sectional views for use in illustrating steps in the method of manufacturing the FPC board 1. FIGS. 2 and 3 are sectional views showing the steps seen from the line A-A of the FPC board 1 of FIG. 1.

First, a two-layer CCL (Copper Clad Laminate) composed of an insulating film 20 made of polyimide and a conductor film 30 made of copper, for example, is prepared as shown in FIG. 2 (a). The thickness of the insulating film 20 is 12.5 μm, and the thickness of the conductor film 30 is 12 μm, for example.

An etching resist 22 is then formed in a given pattern on the conductor film 30 as shown in FIG. 2 (b). The etching resist 22 is formed, for example, by forming a resist film on the conductor film 30 using a dry film resist or the like and exposing the resist film in the given pattern, followed by development.

As shown in FIG. 2 (c), the conductor film 30 excluding regions below the etching resist 22 are subsequently removed by etching. Then, the etching resist 22 is removed by a stripping liquid as shown in FIG. 2 (d). In this manner, the collector portions 3a to 3j, the connection conductor portions 3k to 3n and the drawn-out conductor portions 3o, 3p (see FIG. 1) are formed on the insulating film 20. Note that FIG. 2 (d) only shows the collector portions 3c, 3h, the connection conductor portion 3I and the drawn-out conductor portion 3o.

The collector portions 3a to 3j, the connection conductor portions 3k to 3n and the drawn-out conductor portions 3o, 3p may be formed on the insulating film 20 by a general method such as sputtering, vapor deposition or plating.

Next, a cover film 60 is formed on the insulating film 20 to cover the collector portions 3a to 3j, the connection conductor portions 3k to 3n and the drawn-out conductor portions 3o, 3p by applying or laminating the resin composition containing the electrically conductive material as shown in FIG. 3 (a). The thickness of the cover film 60 is 25 μm, for example.

The cover layers 6a to 6n (see FIG. 1 (a)) are formed by exposing the cover film 60 in a given pattern, followed by development as shown in FIG. 3 (b). Here, the drawn-out electrodes 5a, 5b (see FIG. 1 (a)) are not covered with the cover layers 6a, 6j to be exposed.

As shown in FIG. 3 (c), the insulating film 20 is then cut in a given shape, so that the FPC board 1 including the base insulating layer 2, the collector portions 3a to 3j, the connection conductor portions 3k to 3n, the drawn-out conductor portions 3o, 3p and the cover layers 6a to 6n is completed.

The thickness of the base insulating layer 2 is preferably not less than 1 μm and not more than 100 μm, more preferably not less than 5 μm and not more than 50 μm, and further preferably not less than 5 μm and not more than 30 μm. The base insulating layer 2 having the thickness of not less than 1 μm improves durability and handleability of the FPC board 1. The base insulating layer 2 having the thickness of not more than 100 μm improves flexibility of the FPC board 1, and facilitates reduction in size of the FPC board 1.

The thickness of each of the collector portions 3a to 3j, the connection conductor portions 3k to 3n and the drawn-out conductor portions 3o, 3p is preferably not less than 3 μm and not more than 35 μm, and more preferably not less than 5 μm and not more than 20 μm. The thickness of each of the cover layers 6a to 6n is not less than 1 μm and not more than 300 μm, and more preferably not less than 5 μm and not more than 100 μm.

While the FPC board 1 is manufactured by a subtractive method in FIGS. 2 and 3, the present invention is not limited to this. For example, another manufacturing method such as a semi-additive method may be used. While the cover layers 6a to 6n are formed by an exposure method in FIGS. 2 and 3, the present invention is not limited to this. For example, the cover layers 6a to 6n may be formed by forming a cover film in the given pattern using a printing technique, followed by thermal curing treatment.

(3) Effects

Surfaces of the collector portions 3a to 3j, the connection conductor portions 3k to 3n and the drawn-out conductor portions 3o, 3p provided in the given pattern on the base insulating layer 2 are covered with the cover layers 6a to 6n in the FPC board 1 according to the present embodiment. The resin composition of the cover layers 6a to 6n has moisture permeability of not more than 150 g/(m²·24 h) in the environment at a temperature of 40° C. and a relative humidity of 90%. Alternatively, the resin composition of the cover layers 6a to 6n has the glass transition temperature Tg of not less than 80° C.

In this case, methanol that is a fuel of a fuel cell or products such as formic acid derived from methanol are prevented from permeating through the cover layers 6a to 6n and adhering to the collector portions 3a to 3j, the connection conductor portions 3k to 3n and the drawn-out conductor portions 3o, 3p. Accordingly, the collector portions 3a to 3j, the connection conductor portions 3k to 3n and the drawn-out conductor portions 3o, 3p of the FPC board 1 are sufficiently prevented from corroding.

### [2] Second Embodiment

Description will be made of a fuel cell according to a second embodiment. The fuel cell according to the present embodiment includes the FPC board 1 according to the first embodiment.

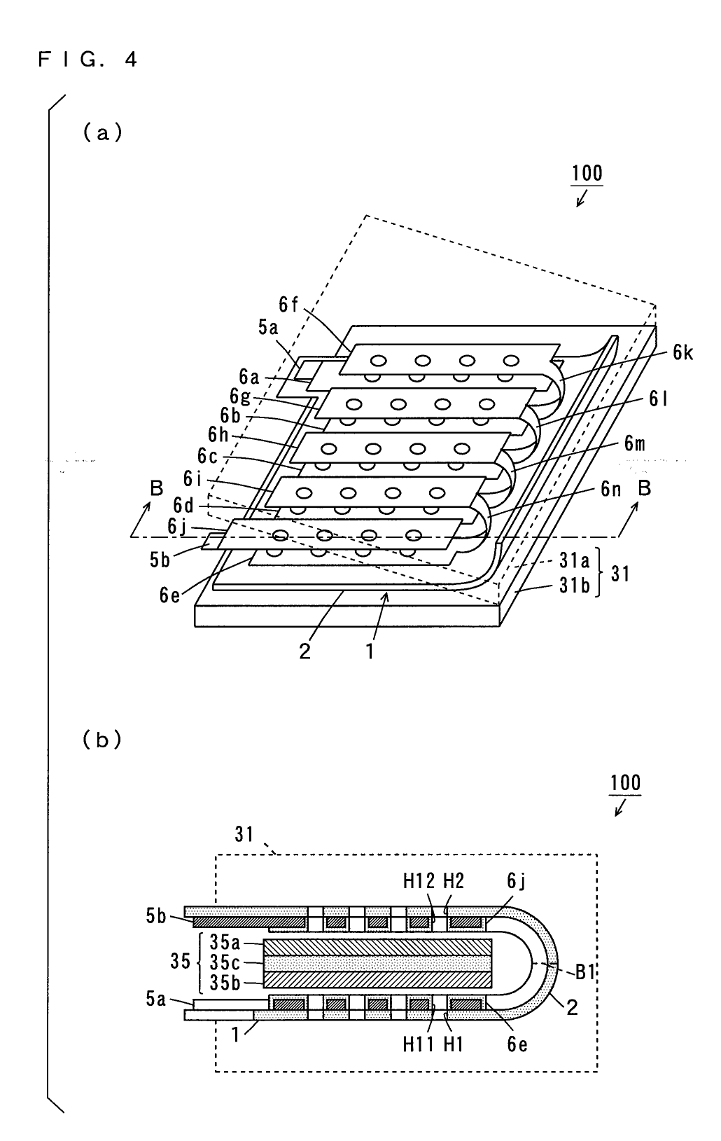

FIG. 4 (a) is an external perspective view of the fuel cell 100 using the FPC board 1, and FIG. 4 (b) is a diagram for illustrating a function in the fuel cell 100. FIG. 4 (b) is a sectional view of the fuel cell 100 of FIG. 4 (a) seen from the line B-B.

As shown in FIG. 4 (a), the fuel cell 100 includes a housing 31 having a rectangular parallelepiped shape and composed of half portions 31a, 31b. FIG. 4 (a) indicates the half portion 31a by the broken line. The FPC board 1 is sandwiched between the half portions 31a, 31b while being bent along the bend portion B1 of FIG. 1 such that the one surface, on which the cover layers 6a to 6n are formed, is positioned on an inner side.

The drawn-out electrodes 5a, 5b of the FPC board 1 are exposed to the outside of the housing 31. Terminals of various external circuits are electrically connected to the drawn-out electrodes 5a, 5b.

As shown in FIG. 4 (b), inside the housing 31, a plurality of (five in the present embodiment) electrode films 35 are arranged between the cover layer 6a and the cover layer 6f, the cover layer 6b and the cover layer 6g, the cover layer 6c and the cover layer 6h, the cover layer 6d and the cover layer 6i, and the cover layer 6e and the cover layer 6j, respectively, of the bent FPC board 1. This causes the plurality of electrode films 35 to be connected in series. Note that FIG. 4 (b) only shows the electrode film 35 arranged between the cover layer 6e and the cover layer 6j.

Each electrode film 35 is composed of a fuel electrode 35a, an air electrode 35b and an electrolyte film 35c. The fuel electrode 35a is formed on one surface of the electrolyte film 35c, and the air electrode 35b is formed on the other surface of the electrolyte film 35c. The fuel electrodes 35a of the plurality of electrode films 35 are opposite to the cover layers 6f to 6j of the FPC board 1, respectively, and the air electrodes 35b of the plurality of electrode films 35 are opposite to the cover layers 6a to 6e of the FPC board 1, respectively.

The fuel is supplied to the fuel electrode 35a of each electrode film 35 through the openings H2, H12 of the FPC board 1. Methanol is used as the fuel in the present embodiment. Air is supplied to the air electrode 35b of each electrode film 35 through the openings H1, H11 of the FPC board 1.

In this case, methanol is decomposed into hydrogen ions and carbon dioxide in the plurality of fuel electrodes 35a, forming electrons. The formed electrons are led from the collector portion 3j (see FIG. 1) to the drawn-out electrode 5b of the FPC board 1. Hydrogen ions decomposed from methanol permeate through the electrolyte films 35c to reach the air electrodes 35b. In the plurality of air electrode 35b, hydrogen ions and oxygen are reacted while electrons led from the drawn-out electrode 5a to the collector portion 3a (see FIG. 1) are consumed, thereby forming water. In this manner, electrical power is supplied to the external circuits connected to the drawn-out electrodes 5a, 5b.

As described above, the FPC board 1 according to the first embodiment is used in the fuel cell 100 according to the second embodiment, so that reliability of the fuel cell 100 can be improved, and the fuel cell 100 can be used over a longer period of time.

### [3] Other Embodiments

While polyimide is used as the material for the base insulating layer 2 of the FPC board 1 in the above-described embodiments, the present invention is not limited to this. Instead of polyimide, another insulating material such as polyamide imide, polyethylene terephthalate, polyethylene naphthalate, polyphenylene sulfide, a liquid crystal polymer, polyolefin or epoxy may be used.

While copper is used as the material for the collector portions 3a to 3j, the connection conductor portions 3k to 3n and the drawn-out conductor portions 3o, 3p, the present invention is not limited to this. Instead of copper, another metal such as gold (Au), silver or aluminum or an alloy such as a copper alloy, a gold alloy, a silver alloy or an aluminum alloy may be used.

While the FPC board 1 includes the five pairs of collector portions (the collector portions 3a, 3f, the collector portions 3b, 3g, the collector portions 3c, 3h, the collector portions 3d, 3i and the collector portions 3e, 3j) in the above-described embodiments, the present invention is not limited to this. The number of the collector portions in the FPC board 1 may be any number of at least two pairs, that is, may be four pairs or less, or six pairs or more. This allows any number of electrode films 35 to be connected in series.

The FPC board 1 may have one pair of collectors. In this case, the connection conductor portions 3k to 3n are not provided.

### [4] Correspondences Between Elements in the Claims and Parts in Embodiments

In the following paragraph, non-limiting examples of correspondences between various elements recited in the claims below and those described above with respect to various preferred embodiments of the present invention are explained.

In the above-described embodiments, the base insulating layer 2 is an example of an insulating layer, the collector portions 3a to 3j, the connection conductor portions 3k to 3n and the drawn-out conductor portions 3o, 3p are examples of a conductor layer, the cover layers 6a to 6n are examples of a cover layer, the FPC board 1 is an example of a printed circuit board, the electrode film 35 is an example of a cell element, the housing 31 is an example of a housing, and the fuel cell 100 is an example of a fuel cell.

As each of various elements recited in the claims, various other elements having configurations or functions described in the claims can be also used. While preferred embodiments of the present invention have been described above, it is to be understood that variations and modifications will be apparent to those skilled in the art without departing the scope and spirit of the present invention. The scope of the present invention, therefore, is to be determined solely by the following claims.

### [5] Examples

### (1) Inventive Examples and Comparative Examples

Resin compositions to be used for the cover layers were formed based on the above-described embodiments in inventive examples 1 to 8 and comparative examples 1 to 5. Then, FPC boards including the cover layers containing the resin compositions were prepared.

In the inventive example 1, an application liquid was prepared by mixing 100 parts by weight of epoxy resin (jER-1007 by Japan Epoxy Resin Co., Ltd.) dissolved in MEK (Methyl Ethyl Ketone), 8 parts by weight of acid anhydride (MH-700 by New Japan Chemical Co., Ltd.) as a curative agent, and 2 parts by weight of imidazole (2E4MZ by Shikoku Chemicals Corporation) as a catalyst. The application liquid was dried and cured, so that a resin composition having the thickness of 25 μm was formed.

In the inventive example 2, a resin composition, which was the same as the resin composition of the inventive example 1 except that 100 parts by weight of epoxy resin (YP50EK35 by Tohto Kasei Co., Ltd.) was added instead of 100 parts by weight of the epoxy resin (jER-1007 by Japan Epoxy Resin Co., Ltd.), was formed.

In the inventive example 3, a resin composition, which was the same as the resin composition of the inventive example 1 except that 50 parts by weight of the epoxy resin (jER-1007 by Japan Epoxy Resin Co., Ltd.) and 50 parts by weight of epoxy resin (EXA-4850 by DIC Corporation) were added instead of 100 parts by weight of the epoxy resin (jER-1007 by Japan Epoxy Resin Co., Ltd.), was formed.

In the inventive example 4, a resin composition, which was the same as the resin composition of the inventive example 1 except that 80 parts by weight of the epoxy resin (jER-1007 by Japan Epoxy Resin Co., Ltd.) and 20 parts by weight of epoxy resin (EPOFRIEND by Daicel Chemical Industries, Ltd.) were added instead of 100 parts by weight of the epoxy resin (jER-1007 by Japan Epoxy Resin Co., Ltd.), was formed.

In the inventive example 5, an application liquid was prepared by mixing 95 parts by weight of resol-type alkylphenol resin (HITANOL 4010 by Hitachi Chemical Co., Ltd.) dissolved in MEK, 5 parts by weight of the epoxy resin (jER-1010 by Japan Epoxy Resin Co., Ltd.), and 2 parts by weight of aminophenol as an addition agent. The application liquid was dried and cured, so that a resin composition having the thickness of 25 μm was formed.

In the inventive example 6, a resin composition, which was the same as the resin composition of the inventive example 1 except for having the thickness of 12 μm, was formed.

In the inventive examples 7 and 8, resin compositions, which were the same as the resin composition of the inventive example 1, were formed.

In the comparative example 1, a resin composition, which was the same as the resin composition of the inventive example 1 except that 80 parts by weight of the epoxy resin (jER-1007 by Japan Epoxy Resin Co., Ltd.) and 20 parts by weight of epoxy resin (YL-7410 by Japan Epoxy Resin Co., Ltd.) were added instead of 100 parts by weight of the epoxy resin (jER-1007 by Japan Epoxy Resin Co., Ltd.), was formed.

In the comparative example 2, a resin composition, which was the same as the resin composition of the comparative example 1 except that 50 parts by weight of the epoxy resin (jER-1007 by Japan Epoxy Resin Co., Ltd.) was added instead of 80 parts by weight of the epoxy resin (jER-1007 by Japan Epoxy Resin Co., Ltd.) and 50 parts by weight of the epoxy resin (YL-7410 by Japan Epoxy Resin Co., Ltd.) was added instead of 20 parts by weight of the epoxy resin (YL-7410 by Japan Epoxy Resin Co., Ltd.), was formed.

In the comparative example 3, a resin composition, which was the same as the resin composition of the comparative example 1 except for having the thickness of 12 μm, was formed.

In the comparative examples 4 and 5, resin compositions, which were the same as the resin composition of the comparative example 2, were formed.

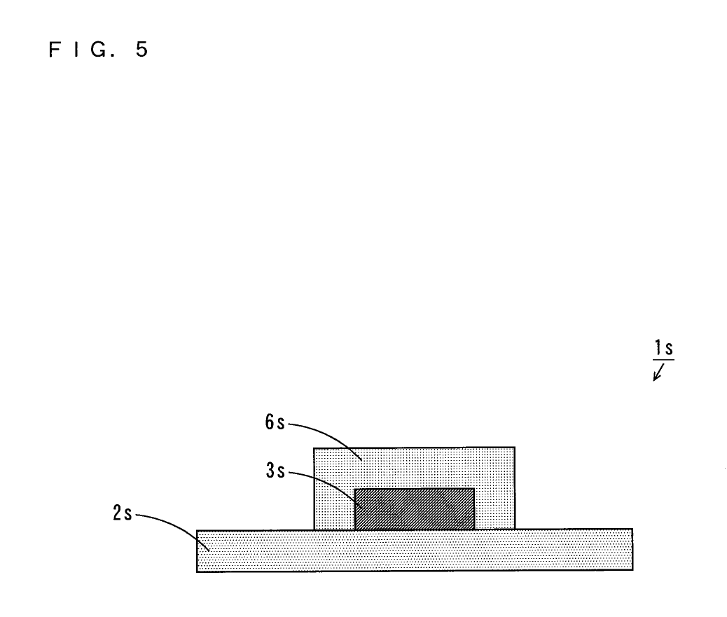

FIG. 5 is a schematic sectional view of the FPC board 1s used in each of the inventive examples 1 to 8 and the comparative examples 1 to 5. As shown in FIG. 5, a conductor layer 3s is formed in a given pattern on a base insulating layer 2s by etching a two-layer CCL using ferric chloride in the FPC board 1s of the inventive examples 1 to 8 and the comparative examples 1 to 5. The conductor layer 3s is covered with a cover layer 6s containing the electrically conductive material and the resin composition.

In the FPC board 1s of the inventive example 1, 18 parts by weight of graphite and 10 parts by weight of carbon black were added to the application liquid of the resin composition of the inventive example 1. The application liquid was applied on the conductor layer 3s of the FPC board 1s, thereby forming the cover layer 6s having the thickness of 25 μm.

In the FPC board 1s of the inventive example 2, a cover layer 6s, which was the same as the cover layer 6s of the inventive example 1 except that the application liquid of the resin composition of the inventive example 2 was used instead of the application liquid of the resin composition of the inventive example 1, was formed on the conductor layer 3s of the FPC board 1s.

In the FPC board 1s of the inventive example 3, a cover layer 6s, which was the same as the cover layer 6s of the inventive example 1 except that the application liquid of the resin composition of the inventive example 3 was used instead of the application liquid of the resin composition of the inventive example 1, was formed on the conductor layer 3s of the FPC board 1s.

In the FPC board 1s of the inventive example 4, a cover layer 6s, which was the same as the cover layer 6s of the inventive example 1 except that the application liquid of the resin composition of the inventive example 4 was used instead of the application liquid of the resin composition of the inventive example 1, was formed on the conductor layer 3s of the FPC board 1s.

In the FPC board 1s of the inventive example 5, a cover layer 6s, which was the same as the cover layer 6s of the inventive example 1 except that the application liquid of the resin composition of the inventive example 5 was used instead of the application liquid of the resin composition of the inventive example 1, was formed on the conductor layer 3s of the FPC board 1s.

In the FPC board 1s of the inventive example 6, a cover layer 6s, which was the same as the cover layer 6s of the inventive example 1 except that the application liquid of the resin composition of the inventive example 6 was used instead of the application liquid of the resin composition of the inventive example 1 and the thickness of the cover layer 6s was 12 μm, was formed on the conductor layer 3s of the FPC board 1s.

In the FPC board 1s of the inventive example 7, 10 parts by weight of electrically conductive carbon black (Ketjenblack EC-DJ600 by Lion Co., Ltd.) and 45 parts by weight of graphite (by Nippon Graphite Industries, Co., Ltd.) as electrically conductive components were previously mixed in 45 parts by weight of the application liquid of the resin composition of the inventive example 1. Then, the electrically conductive carbon black and graphite in the mixture were dispersed using a three-roller apparatus, thereby forming a precursor of the cover layer 6s. The precursor was applied on the conductor layer 3s of the FPC board 1s, thereby forming the cover layer 6s having the thickness of 25 μm.

In the FPC board 1s of the inventive example 8, 70 parts by weight of silver particles (FA series by DOWA Hightech Co., Ltd.) as an electrically conductive component was prepared, and previously mixed in 30 parts by weight of the application liquid of the resin composition of the inventive example 1. Then, the silver particles in the mixture were dispersed using a three-roller apparatus, thereby forming a precursor of the cover layer 6s. The precursor was applied on the conductor layer 3s of the FPC board 1s, thereby forming the cover layer 6s having the thickness of 25 μm.

In the FPC board 1s of the comparative example 1, a cover layer 6s, which was the same as the cover layer 6s of the inventive example 1 except that the application liquid of the resin composition of the comparative example 1 was used instead of the application liquid of the resin composition of the inventive example 1, was formed on the conductor layer 3s of the FPC board 1s.

In the FPC board 1s of the comparative example 2, a cover layer 6s, which was the same as the cover layer 6s of the inventive example 1 except that the application liquid of the resin composition of the comparative example 2 was used instead of the application liquid of the resin composition of the inventive example 1, was formed on the conductor layer 3s of the FPC board 1s.

In the FPC board 1s of the comparative example 3, a cover layer 6s, which was the same as the cover layer 6s of the inventive example 1 except that the application liquid of the resin composition of the comparative example 3 was used instead of the application liquid of the resin composition of the inventive example 1 and the thickness of the cover layer 6s was 12 μm, was formed on the conductor layer 3s of the FPC board 1s.

In the FPC board 1s of the comparative example 4, 10 parts by weight of the electrically conductive carbon black (Ketjenblack EC-DJ600 by Lion Co., Ltd.) and 45 parts by weight of the graphite (by Nippon Graphite Industries, Co., Ltd.) as electrically conductive components were previously mixed in 45 parts by weight of the application liquid of the resin composition of the comparative example 2. Then, the electrically conductive carbon black and graphite in the mixture were dispersed using a three-roller apparatus, thereby forming a precursor of the cover layer 6s. The precursor was applied on the conductor layer 3s of the FPC board 1s, thereby forming the cover layer 6s having the thickness of 25 μm.

In the FPC board 1s of the comparative example 5, 70 parts by weight of the silver particles (FA series by DOWA Hightech Co., Ltd.) as an electrically conductive component was previously mixed in 30 parts by weight of the application liquid of the resin composition of the comparative example 2. Then, the silver particles in the mixture were dispersed using a three-roller apparatus, thereby forming a precursor of the cover layer 6s. The precursor was applied on the conductor layer 3s of the FPC board 1s, thereby forming the cover layer 6s having the thickness of 25 μm.

### (2) Moisture Permeability and Glass Transition Temperature of the Resin Composition and Corrosion Resistance Effects of the Cover Layers

The moisture permeability and glass transition temperature Tg of each of the resin compositions of the inventive examples 1 to 8 and the comparative examples 1 to 5 were measured. Also, corrosion resistance effects of the cover layer 6s of each of the FPC boards 1s of the inventive examples 1 to 8 and the comparative examples 1 to 5 were evaluated.

The moisture permeability of each of the resin compositions of the inventive examples 1 to 8 and the comparative examples 1 to 5 was measured by the cup method (JIS Z0208) described below. In the cup method, calcium chloride, which is an absorbent, was filled in a cup. Then, each of the resin compositions of the inventive examples 1 to 8 and the comparative examples 1 to 5 was attached to cover an opening of the cup, and the peripheral edge of the cup was sealed by sealing wax.

The cup was left for 24 hours in an environment at a temperature of 40° C. and with a relative humidity of 90%, and an amount of increase in mass of calcium chloride after being left was measured, so that mass M [mg] of water vapor that permeates through the resin composition in a moisture permeability area S [cm²] per 24 hours was measured. The moisture permeability WVTRₛₐₘₚₗₑ is calculated by the following equation:

WVTRₛₐₘₚₗₑ=240×M/(T·S)[g/(m²·24 h)]

The glass transition temperature Tg of each of the resin compositions of the inventive examples 1 to 8 and the comparative examples 1 to 5 was measured using the viscoelasticity measurement device RSAIII (TA Instruments Japan Co., Ltd.).

Corrosion resistance effects of the cover layer 6s of each of the FPC boards 1s of the inventive examples 1 to 8 and the comparative examples 1 to 5 were evaluated by the following immersion test. The FPC boards 1s of the inventive examples 1 to 8 and the comparative examples 1 to 5 were immersed in an aqueous methanol solution at a temperature of 60° C. and a concentration of 10% for seven days. After that, a corrosion state of the appearance of the conductor layer 3s of each FPC board 1s was observed, so that the corrosion resistance effects of the cover layer 6s were evaluated.

Table 1 shows measurement results of the moisture permeability and glass transition temperature Tg of each resin composition and results of the immersion test of each FPC board 1s.

TABLE 1

| | | GLASS | |
|---|---|---|---|
| | MOISTURE | TRANSITION | |
| | PERMEABILITY | TEMPERATURE | IMMERSION |
| | [g/(m² · 24 h)] | Tg [° C.] | TEST |
| INVENTIVE | 93 | 111 | ∘ |
| EXAMPLE 1 | | | |
| INVENTIVE | 131 | 103 | ∘ |
| EXAMPLE 2 | | | |
| INVENTIVE | 105 | 92 | ∘ |
| EXAMPLE 3 | | | |
| INVENTIVE | 135 | 111 | ∘ |
| EXAMPLE 4 | | | |
| INVENTIVE | 40 | 169 | ∘ |
| EXAMPLE 5 | | | |
| INVENTIVE | 145 | 111 | ∘ |
| EXAMPLE 6 | | | |
| INVENTIVE | 93 | 111 | ∘ |
| EXAMPLE 7 | | | |
| INVENTIVE | 93 | 111 | ∘ |
| EXAMPLE 8 | | | |
| COMPARATIVE | 155 | 75 | x |
| EXAMPLE 1 | | | |
| COMPARATIVE | 250 | 28 | x |
| EXAMPLE 2 | | | |
| COMPARATIVE | 260 | 75 | x |
| EXAMPLE 3 | | | |
| COMPARATIVE | 250 | 28 | x |
| EXAMPLE 4 | | | |
| COMPARATIVE | 250 | 28 | x |
| EXAMPLE 5 | | | |

As shown in Table 1, the moisture permeability of the resin composition of the inventive example 1 was 93 g/(m²·24 h), and the glass transition temperature Tg was 111° C. As a result of the immersion test, corrosion was not observed in the conductor layer 3s of the FPC board 1s of the inventive example 1.

The moisture permeability of the resin composition of the inventive example 2 was 131 g/(m²·24 h), and the glass transition temperature Tg was 103° C. As a result of the immersion test, corrosion was not observed in the conductor layer 3s of the FPC board 1s of the inventive example 2.

The moisture permeability of the resin composition of the inventive example 3 was 105 g/(m²·24 h), and the glass transition temperature Tg was 92° C. As a result of the immersion test, corrosion was not observed in the conductor layer 3s of the FPC board 1s of the inventive example 3.

The moisture permeability of the resin composition of the inventive example 4 was 135 g/(m²·24 h), and the glass transition temperature Tg was 111° C. As a result of the immersion test, corrosion was not observed in the conductor layer 3s of the FPC board 1s of the inventive example 4.

The moisture permeability of the resin composition of the inventive example 5 was 40 g/(m²·24 h), and the glass transition temperature Tg was 169° C. As a result of the immersion test, corrosion was not observed in the conductor layer 3s of the FPC board 1s of the inventive example 5.

The moisture permeability of the resin composition of the inventive example 6 was 1450 g/m²·24 h), and the glass transition temperature Tg was 111° C. As a result of the immersion test, corrosion was not observed in the conductor layer 3s of the FPC board 1s of the inventive example 6.

The moisture permeability of the resin composition of the inventive example 7 was 93 g/(m²·24 h), and the glass transition temperature Tg was 111° C. As a result of the immersion test, corrosion was not observed in the conductor layer 3s of the FPC board 1s of the inventive example 7.

The moisture permeability of the resin composition of the inventive example 8 was 93 g/(m²·24 h), and the glass transition temperature Tg was 111° C. As a result of the immersion test, corrosion was not observed in the conductor layer 3s of the FPC board 1s of the inventive example 8.

Meanwhile, the moisture permeability of the resin composition of the comparative example 1 was 155 g/(m²·24 h), and the glass transition temperature Tg was 75° C. As a result of the immersion test, corrosion was observed in the conductor layer 3s of the FPC board 1s of the comparative example 1.

The moisture permeability of the resin composition of the comparative example 2 was 250 g/(m²·24 h), and the glass transition temperature Tg was 28° C. As a result of the immersion test, corrosion was observed in the conductor layer 3s of the FPC board 1s of the comparative example 2.

The moisture permeability of the resin composition of the comparative example 3 was 260 g/(m²·24 h), and the glass transition temperature Tg was 75° C. As a result of the immersion test, corrosion was observed in the conductor layer 3s of the FPC board 1s of the comparative example 3.

The moisture permeability of the resin composition of the comparative example 4 was 250 g/(m²·24 h), and the glass transition temperature Tg was 28° C. As a result of the immersion test, corrosion was observed in the conductor layer 3s of the FPC board 1s of the comparative example 4.

The moisture permeability of the resin composition of the comparative example 5 was 250 g/(m²·24 h), and the glass transition temperature Tg was 28° C. As a result of the immersion test, corrosion was observed in the conductor layer 3s of the FPC board 1s of the comparative example 5.

The results of the inventive examples 1 to 8 and the comparative examples 1 to 5 show the conductor layer 3s of the FPC board 1s was sufficiently prevented from corroding when the moisture permeability of the resin composition contained in the cover layer 6s of the FPC board 1s was not more than 150 g/(m²·24 h) or the glass transition temperature Tg was not less than 80° C.

I/We claim:

1. A printed circuit board to be used in a fuel cell, comprising:
an insulating layer;
a conductor layer that is provided in a given pattern on said insulating layer; and
a cover layer that covers a surface of said conductor layer, wherein
said cover layer contains an electrically conductive material and a resin composition, and
said resin composition has moisture permeability of not more than 150 g/(m²·24 h) in an environment at a temperature of 40° C. and with a relative humidity of 90%.

2. The printed circuit board according to claim 1, wherein said cover layer contains not less than 5 parts by weight and not more than 70 parts by weight of said electrically conductive material relative to 100 parts by weight of said resin composition.

3. The printed circuit board according to claim 1, wherein said resin composition includes at least one of phenol resin, epoxy resin, acrylic resin, polyurethane resin, polyimide resin, polyamide imide resin and polyester resin.

4. The printed circuit board according to claim 1, wherein said electrically conductive material includes at least one of a metal material, a carbon material and an electrically conductive polymeric material.

5. The printed circuit board according to claim 4, wherein said metal material includes silver.

6. The printed circuit board according to claim 4, wherein said carbon material includes at least one of carbon black and graphite.

7. A fuel cell comprising:
the printed circuit board according to claim 1;
a cell element: and
a housing that accommodates said printed circuit board and said cell element.

8. A printed circuit board to be used in a fuel cell, comprising:
an insulating layer;
a conductor layer that is provided in a given pattern on said insulating layer; and
a cover layer that covers a surface of said conductor layer, wherein
said cover layer contains an electrically conductive material and a resin composition, and
said resin composition has a glass transition temperature of not less than 80° C.

9. The printed circuit board according to claim 8, wherein said cover layer contains not less than 5 parts by weight and not more than 70 parts by weight of said electrically conductive material relative to 100 parts by weight of said resin composition.

10. The printed circuit board according to claim 8, wherein said resin composition includes at least one of phenol resin, epoxy resin, acrylic resin, polyurethane resin, polyimide resin, polyamide imide resin and polyester resin.

11. The printed circuit board according to claim 8, wherein said electrically conductive material includes at least one of a metal material, a carbon material and an electrically conductive polymeric material.

12. The printed circuit board according to claim 11, wherein said metal material includes silver.

13. The printed circuit board according to claim 11, wherein said carbon material includes at least one of carbon black and graphite.

14. A fuel cell comprising:
the printed circuit board according to claim 8;
a cell element; and
a housing that accommodates said printed circuit board and said cell element.
